(19) United States
(12) Patent Application Publication
(10) Pub. No.: US 2009/0173969 A1
(43) Pub. Date: Jul. 9, 2009

(54) Semiconductor Device

(76) Inventors: Junjiro Kikawa, Shiga-ken (JP); Akira Suzuki, Shiga-ken (JP); Masayoshi Kosaki, Aichi-ken (JP); Koji Hirata, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 12/225,580

(22) PCT Filed: May 30, 2007
(86) PCT No.: PCT/JP2007/061412

§ 371 Date: Nov. 25, 2008

(30) Foreign Application Priority Data
May 31, 2006 (JP) 2006-152753

(51) Int. Cl. H01L 29/778; H01L 33/00

(52) U.S. Cl. 257/194; 257/189; 257/E29.246; 257/E33.034

(57) ABSTRACT

A semiconductor device having an AlGaN—GaN heterojunction structure including an AlGaN layer and a GaN layer which device exhibits no changes over time in sheet resistance.

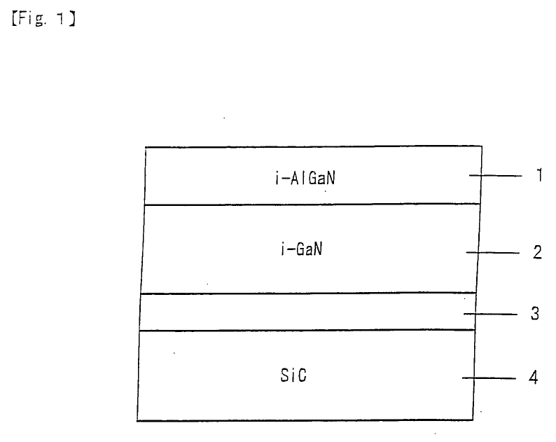

As shown in FIG. 1, in a semiconductor device having an AlGaN—GaN heterojunction structure including an AlGaN layer 1 and a GaN layer 2, when the Al molar fraction of AlGaN (x %) and the thickness of the AlGaN layer (y nm) satisfy the relations: x+y<55, 25≦x≦40, and y≧10, y is smaller than the critical thickness, whereby no cracks are generated in the AlGaN layer. Therefore, the invention provides a semiconductor device exhibiting virtually no changes over time in sheet resistance despite high Al molar fraction.

### TECHNICAL FIELD

The present invention relates to a group III nitride semiconductor device exhibiting little change over time in sheet resistance.

### BACKGROUND ART

In recent years, group III nitride semiconductor materials have been remarkably developed through extensive studies thereon for application to LEDs and LDs. Recently, the semiconductor materials have been further studied for application to semiconductor devices other than LEDs and LDs, and application of the materials is now promising. By virtue of particular properties of a nitrogen atom, group III nitride semiconductors exhibit intense piezoelectric effect and spontaneous polarization. Therefore, in an AlGaN—GaN heterojunction structure, the heterojunction interface can be imparted with a large 2-dimensional electron gas density without performing modulation doping; i.e., in a non-doped state. Thus, group III nitride semiconductors are promising materials for producing HEMT devices.

One conceivable approach to enhance the 2-dimensional electron gas density is to increase the Al molar fraction of AlGaN, to thereby enhance piezoelectric effect. However, when this approach is employed to increase the 2-dimensional electron gas density, in some cases, an increase over time in sheet resistance of the AlGaN layer is observed. Thus, electronic devices produced through such a technique fail to have reliability.

The aforementioned changes over time in sheet resistance are conceivably caused by micro-cracks in AlGaN growing as time passes. In other words, it is considered that as cracks propagate over time and reach the vicinity of the heterojunction interface, the surface area of AlGaN increases on account of the increase of glide planes of the cracks. This promotes depletion of a surface energy level in the AlGaN layer, whereby the density of the carriers is reduced, to thereby elevate sheet resistance. In addition, interception of current paths by cracking is conceived to be another reason for the increase in sheet resistance.

A possible main reason for generation of cracks is that difference in lattice constants between AlGaN and GaN provides strain and the strain increases as the thickness of the AlGaN layer increases. When the thickness exceeds a certain value (referred to as a “critical thickness”), the thus-provided intolerable strain generates cracks in the layer.

Therefore, one conceivable approach to prevent crack generation is to regulate the AlGaN thickness to be equal to or less than the critical thickness.

Non-patent Document 1 discloses a theoretical formula for calculating the critical thickness. According to the formula, when the Poisson's ratios and lattice constants of AlGaN and GaN are given, the critical thickness can be calculated. Notably, the Poisson's ratio and the lattice constants of AlGaN vary in accordance with the Al molar fraction. Therefore, in the AlGaN—GaN heterojunction structure, the critical thickness of the AlGaN layer depends on the Al molar fraction of AlGaNa.

Regarding the thickness of an AlGaN layer, Patent Document 1 discloses a thickness of 25 nm when the Al molar fraction is 30%, and Patent Document 2 discloses a thickness of 25 nm when the Al molar fraction is 20%. However, both documents fail to teach the reason why the thickness is employed, and never describe changes over time in sheet resistance.

Other approaches to prevent generation of cracks are also disclosed. Patent Document 3 discloses an approach through doping with magnesium, and Patent Document 4 discloses an approach through forming an AlN layer between an AlGaN layer and a GaN layer.
Patent Document 1: Japanese Patent Application Laid-Open (kokai) No. 2001-284576
Patent Document 2: Japanese Patent Application Laid-Open (kokai) 2004-200248
Patent Document 3: Japanese Patent No. 3441329
Patent Document 4: Japanese Patent Application Laid-Open (kokai) No. 2004-119783
Non-Patent Document 1: J. W. Matthews and A. E. Blakeslee, J. Cryst. Growth, 27, 118(1974)
Non-Patent Document 2: Polian, A., M. Grimsditch, I. Grzegory, J. Appl. Phys. 79(6) (1996), 3343-3344
Non-Patent Document 3: Thokala, R, Chaudhuri J., Thin Solid Films 266, 2 (1995), 189-191

### DISCLOSURE OF THE INVENTION

### Problems to be Solved by the Invention

However, attempts to calculate the critical thickness using the theoretical formula disclosed in Non-Patent Document 1 unexpectedly encounter difficulty. This is due to inconsistency among relevant academic societies in reporting values of material constants (e.g., Poisson's ratio and lattice constants) of AlGaN and GaN crystals. These material constants vary depending on the crystal growth method, the epitaxial structure, or other factors. Therefore, the thus-calculated critical thickness values vary depending on the selected material constants, and the theoretical values do not correctly reflect actual critical thickness values.

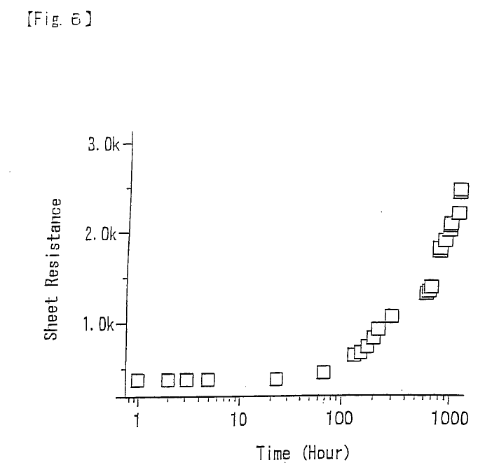

In a specific case, a lattice constant and Poisson's ratio of AlGaN having an Al molar fraction of 30% are calculated through interpolation with the Vergard's law from, for example, a lattice constant of GaN of 5.185 and a Poisson's ratio of GaN of 0.352 (disclosed in Non-Patent Document 2) and a lattice constant of AlN of 4.982 and a Poisson's ratio of AlN of 0.287 (disclosed in Non-Patent Document 3). Through calculation on the basis of the theoretical formula disclosed in Non-Patent Document 1 from the thus-obtained lattice constant and Poisson's ratio, a critical thickness of the AlGaN layer of 37 nm is obtained. Separately, changes over time in sheet resistance of an actual AlGaN layer having an Al molar fraction of 30% and a thickness of 30 nm were observed. As shown in the graph given in FIG. 6, even though the AlGaN layer has a thickness of 30 nm, which is smaller than the aforementioned critical thickness, sheet resistance was found to drastically increase after elapse of time of about 100 hours. This indicates that the thus-calculated theoretical value of critical thickness is considerably deviated from an actual value of critical thickness. Notably, in the graph given in FIG. 6, the lateral axis is represented by a logarithmic scale.

Through repeated experiments, the present invention has been conceived on the basis of the existence of a specific relationship between the Al molar fraction of AlGaN and the critical thickness of an AlGaN layer. Thus, an object of the invention is to realize a semiconductor device which has an AlGaN—GaN heterojunction structure and which exhibits small changes over time in sheet resistance, through regulating the thickness of the AlGaN layer to be equal to or less than the critical thickness.

Another object of the invention is to realize a semiconductor device which has an AlGaN—GaN heterojunction structure and which exhibits small changes over time in sheet resistance, through employment of a novel structure.

### Means for Solving the Problems

In a first aspect of the present invention, there is provided a semiconductor device having an AlGaN—GaN heterojunction structure including an AlGaN layer and a GaN layer, characterized in that the AlGaN layer has an Al molar fraction (x %) and a thickness (y nm), wherein x and y satisfy the following relations: x+y<55, 25≦x≦40, and y≧10.

The value of y calculated from the equation: y=55−x corresponds to the critical thickness of an AlGaN layer having an Al molar fraction of x %. The critical thickness has been first obtained through repeated experiments. When the Al molar fraction and the thickness fall within the ranges of the first aspect of the invention, the AlGaN layer has a thickness smaller than the critical thickness. The condition y≧10 is employed, since if the thickness is less than 10 nm, uniform film is difficult to form, and pits, which increase resistance, may be generated. The AlGaN layer and the GaN layer may be doped with an impurity element such as Mg. The parameter “x” preferably falls within the range: 25≦x≦40, most preferably 30≦x≦35. The condition x≧40 is not preferred, since the critical thickness is excessively small in the range, and a uniform AlGaN layer is difficult to form.

In a second aspect of the present invention, there is provided a semiconductor device having an AlGaN—GaN heterojunction structure including an AlGaN layer and a GaN layer, characterized in that the device has an intrinsic GaN layer (hereinafter referred to as i-GaN layer) on a surface of the AlGaN layer opposite the surface of the AlGaN layer to which the GaN layer has been joined, that the AlGaN layer has an Al molar fraction of 30% to 40% and a thickness of 30 nm to 45 nm, and that the i-GaN layer has a thickness of 5 nm to 100 nm.

The second aspect of the invention is preferred for increasing the thickness of the AlGaN layer while the Al molar fraction is maintained at a high level. Specifically, the thickness can be increased to 30 nm or more at an Al molar fraction of ≧30%, whereby the thickness of the AlGaN layer can exceed the critical thickness. In a third aspect of the present invention, the i-GaN layer preferably has a thickness of 20 nm or less. A thickness of 100 nm or more of the i-GaN layer is not preferred, since strain in AlGaN is excessively relaxed, and an Ohmic electrode is difficult to form on the i-GaN layer. Thus, the i-GaN layer preferably has a thickness of 5 nm or more. When the thickness is less than 5 nm, effect of relaxing the strain fails to be attained. The Al molar fraction is preferably 40% or less, and the AlGaN layer preferably has a thickness of 40 nm or less. In a fourth aspect of the invention, the AlGaN layer is joined to the i-GaN layer. Needless to say, the two layers are not necessarily joined to each other. For example, a metallic film may intervene between the AlGaN layer and the i-GaN layer. In the second to fourth aspects of the invention, similar to the first aspect, the AlGaN layer and the GaN layer may be doped.

In a fifth aspect of the invention, there is provided an HEMT employing a device of the first aspect. In a sixth aspect, there is provided an HEMT employing a device of any of the second to fourth aspects.

### Effects of the Invention

According to the semiconductor device of the first aspect of the invention, the AlGaN layer has a thickness smaller than the critical thickness determined through experiments. Therefore, generation of cracks and changes over time in sheet resistance are prevented.

The semiconductor device of the second aspect of the invention is provided with an i-GaN layer (intrinsic GaN layer). Thus, even though the AlGaN layer has a thickness greater than the critical thickness, strain in the AlGaN layer can be compensated, to thereby prevent generation of cracks. Similar to the first aspect of the invention, the semiconductor device exhibits small changes over time in sheet resistance.

An HEMT device produced from the semiconductor device according to the present invention has a high Al molar fraction. Therefore, high 2-dimensional electron gas density at an heterojunction interface can be attained, whereby a useful HEMT device which does not exhibit deterioration in performance over time can be produced.

### BEST MODES FOR CARRYING OUT THE INVENTION

With reference to the drawings, the present invention will next be described in detail by way of examples, which should not be construed as limiting the invention thereto.

### Example 1

In Example 1, a semiconductor device as shown in FIG. 1 having a heterojunction structure formed from an AlGaN layer 1 and a GaN layer 2 was produced. Similar semiconductor devices having different Al molar fractions and thicknesses of the AlGaN layer 1 were also produced, and changes over time in sheet resistance were observed for the produced devices.

In Example 1, each semiconductor device was produced by forming, through MOCVD, an AlN buffer layer 3 on an SiC substrate 4, a GaN layer 2 on the buffer layer, and an AlGaN layer 1 on the GaN layer. The AlGaN layer 1 and the GaN layer 2 were non-doped. The GaN layer 2 had a thickness of 2 μm.

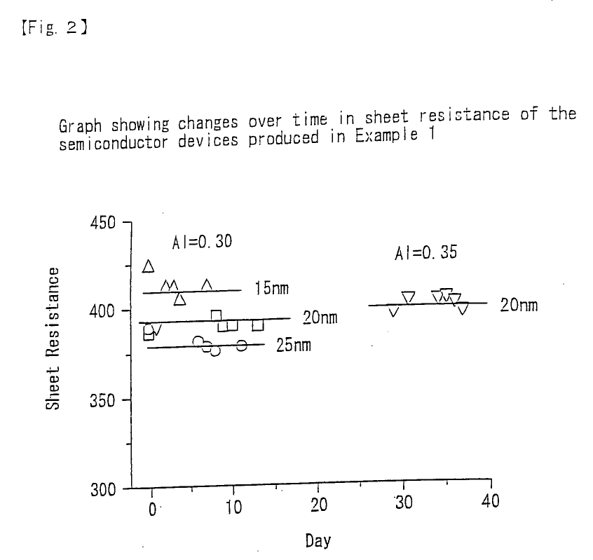

Specifically, four devices (Al molar fraction: 30%, thickness of AlGaN layer 1: 15, 20, and 25 nm, and Al molar fraction: 35%, thickness of AlGaN layer 1: 20 nm) were produced. Changes over time in sheet resistance were monitored for the four devices. The results are shown in the graph given in FIG. 2. In FIG. 2, sheet resistance values of the device (Al molar fraction: 30%, thickness: 15 nm) are represented by triangles; those of the device (Al molar fraction: 30%, thickness: 20 nm) are represented by squares; those of the device (Al molar fraction: 30%, thickness: 25 nm) are represented by circles; and those of the device (Al molar fraction: 35%, thickness: 20 nm) are represented by inverted triangles. As shown in the graph given in FIG. 2, tested devices (Al molar fraction: 30%, thickness: 15, 20, and 25 nm) exhibited substantially no changes in sheet resistance over about 10 days, and a tested device (Al molar fraction: 35%, thickness: 20 nm) exhibited substantially no changes in sheet resistance over about 40 days. In each case, measured resistance values varied slightly. However, the tested devices did not exhibited significant increase in sheet resistance, which had been observed for conventional devices about 100 hours after the start of the test as shown in the graph given in FIG. 6. The slight variations in measured resistance values may be attributable to temperature variation by about 1° C. to 2° C. at the measurement and are not caused by generation of cracks.

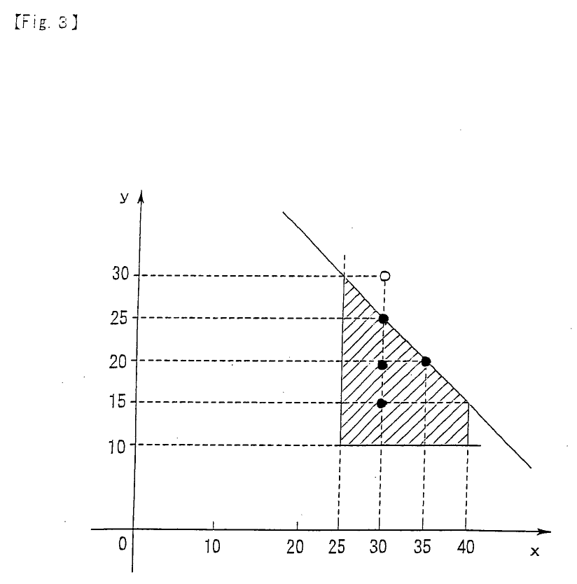

Data of the Al molar fraction (x %) of the AlGaN layer 1 and the thickness (y nm) of the AlGaN layer 1 given in FIGS. 2 and 6 were plotted in a graph with a lateral axis (x) and a vertical axis (y) shown in FIG. 3. In FIG. 3, data sets (x, y) in which no changes over time in sheet resistance were observed are represented by black circles, whereas a data set (x, y) in which changes over time in sheet resistance were observed is represented by a white circle. Thus, semiconductor devices exhibiting a data set falling within a slant-lined area shown in FIG. 3 are conceived to exhibit no changes over time in sheet resistance.

### Example 2

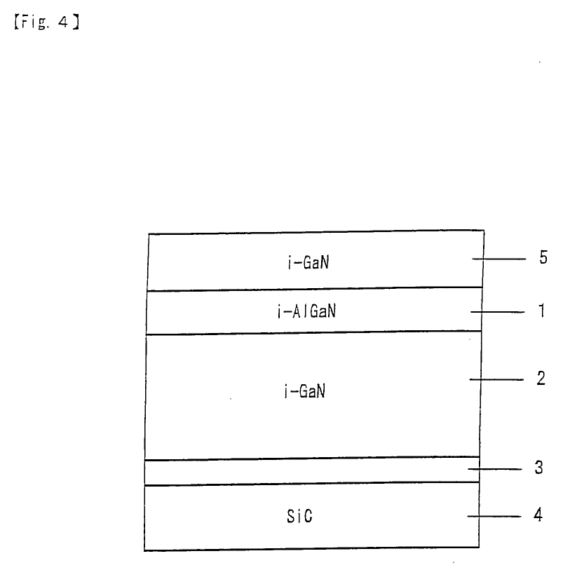

In Example 2, a semiconductor device as shown in FIG. 4 having a structure having an AlGaN layer 1 joined to the upper surface of a GaN layer 2, and an i-GaN layer 5, i.e., an intrinsic or un-doped GaN layer, joined to the upper surface of the AlGaN layer 1 was produced. The AlGaN layer 1, GaN layer 2, and GaN layer 5 are un-doped, i.e., intrinsic. The GaN layer 2 has a thickness of 2 μm, the AlGaN layer 1 has an Al molar fraction of 30% and a thickness of 30 nm, and the i-GaN layer 5 has a thickness of 75 nm.

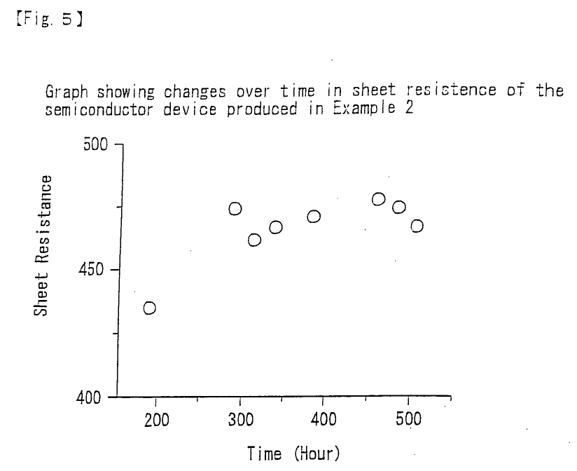

Changes over time in sheet resistance were monitored in a manner similar to that of Example 1, and the results are shown in FIG. 5. Similar to Example 1, although the measured sheet resistance values have slight variations conceivably due to temperature variation, no significant changes in sheet resistance were observed from hour 300 to hour 500, after production of the test device.

### INDUSTRIAL APPLICABILITY

The semiconductor device of the present invention can be employed for producing semiconductor devices such as HEMT devices, and can prolong the service life of the semiconductor devices produced therefrom.

### BRIEF DESCRIPTION OF THE DRAWINGS

[FIG. 1] A semiconductor device of Example 1.

[FIG. 2] A graph showing changes over time in sheet resistance of the semiconductor devices produced in Example 1.

[FIG. 3] A graph showing the relation between the Al molar fraction of the AlGaN layer and the thickness of the AlGaN layer, specifying the area where the semiconductor devices exhibits no changes over time in sheet resistance.

[FIG. 4] A semiconductor device of Example 2.

[FIG. 5] A graph showing changes over time in sheet resistance of the semiconductor device produced in Example 2.

[FIG. 6] A graph showing changes over time in sheet resistance of a semiconductor device.

### DESCRIPTION OF REFERENCE NUMERALS

1: AlGaN layer
2: GaN layer
3: Buffer layer
4: SiC substrate
5: GaN layer

1. A semiconductor device having an AlGaN—GaN heterojunction structure including an AlGaN layer and a GaN layer, wherein the AlGaN layer has an Al molar fraction (x %) and a thickness (y nm), wherein x and y satisfy the following relations: x+y<55, 25≦x≦40, and y≧10.

2. A semiconductor device having an AlGaN—GaN heterojunction structure including an AlGaN layer and a GaN layer, wherein the device has an intrinsic i-GaN layer on a surface of the AlGaN layer opposite the surface of the AlGaN layer to which the GaN layer has been joined, the AlGaN layer has an Al molar fraction of 30% to 40% and a thickness of 30 nm to 45 nm, and the intrinsic i-GaN layer has a thickness of 5 nm to 100 nm.

3. A semiconductor device as described in claim 2, wherein the intrinsic i-GaN layer has a thickness of 5 nm to 20 nm.

4. A semiconductor device as described in claim 2, wherein the AlGaN layer and the intrinsic i-GaN layer are joined to each other.

5. A semiconductor device as described in claim 1, which comprises an HEMT, wherein
the AlGaN layer serves as a barrier layer,
the GaN layer serves as a channel layer, and
2-dimensional electron gas is formed at a junction interface between the AlGaN layer and the GaN layer.

6. A semiconductor device as described in claim 2, which comprises an HEMT, wherein
the AlGaN layer serves as a barrier layer,
the GaN layer serves as a channel layer,
the intrinsic i-GaN layer serves as a capping layer, and
2-dimensional electron gas is formed at a junction interface between the AlGaN layer and the GaN layer.

7. A semiconductor device as described in claim 3, wherein the AlGaN layer and the intrinsic i-GaN layer are joined to each other.

8. A semiconductor device as described in claim 3, which comprises an HEMT, wherein
the AlGaN layer serves as a barrier layer,
the GaN layer serves as a channel layer,
the intrinsic i-GaN layer serves as a capping layer, and
2-dimensional electron gas is formed at a junction interface between the AlGaN layer and the GaN layer.

9. A semiconductor device as described in claim 4, which comprises an HEMT, wherein
the AlGaN layer serves as a barrier layer,
the GaN layer serves as a channel layer,
the intrinsic i-GaN layer serves as a capping layer, and
2-dimensional electron gas is formed at a junction interface between the AlGaN layer and the GaN layer.
